(19) United States
(12) Patent Application Publication
(10) Pub. No.: US 2026/0173600 A1
(43) Pub. Date: Jun. 18, 2026

(54) COMPONENT AND OPTOELECTRONIC DEVICE COMPRISING STRUCTURES FOR REDUCING OPTICAL CROSSTALK

(71) Applicant: ams-OSRAM International GmbH, Regensburg (DE)

(72) Inventors: Ali Mahdavi, Muenchen (DE); Alvaro Gomez-Iglesias, Regensburg (DE)

(21) Appl. No.: 18/707,813

(22) PCT Filed: Nov. 3, 2022
(86) PCT No.: PCT/EP2022/080656

§ 371 Date: May 6, 2024

(30) Foreign Application Priority Data
Nov. 9, 2021 (DE) 10 2021 129 118.6

(51) Int. Cl. H10H 20/853

(52) U.S. Cl. CPC H10H 20/853

(57) ABSTRACT

In an embodiment a component includes a semiconductor body and a cover region, wherein the semiconductor body has a first semiconductor layer, a second semiconductor layer and an active zone arranged therebetween, the active zone configured for generating electromagnetic radiation, wherein the cover region is configured for electrically contacting the first semiconductor layer, and wherein the cover region has a larger lateral cross-section than the active zone and has an edge region, which does not overlap with the active zone in plan view, and vertical depressions, which are located exclusively in the edge region of the cover region and, in plan view, do not overlap with the active zone, the vertical depressions being configured to reduce lateral optical crosstalk.

### CROSS-REFERENCE TO RELATED APPLICATIONS

This patent application is a national phase filing under section 371 of PCT/EP2022/080656, filed Nov. 3, 2022, which claims the priority of German patent application 102021129118.6, filed Nov. 9, 2021, each of which is incorporated herein by reference in its entirety.

### TECHNICAL FIELD

A component comprising structures for reducing optical crosstalk is disclosed. Such structures are also suitable for improving the directionality of the radiation emission and for achieving an improved light extraction efficiency (LEE) of the component. Further disclosed is an optical device comprising a plurality of components.

### BACKGROUND

A component, in particular an optoelectronic component, usually has an upper contact layer that is sufficiently thick to ensure efficient lateral current extension. However, a thick contact layer can lead to strong optical cross-talk. Metal grids can be used to reduce the optical cross-talk. However, metal grids are usually highly absorbent and often difficult to implement. The disadvantages of using metal grids are often high light losses and no effective suppression of crosstalk. Another way to reduce optical crosstalk is to roughen the upper contact layer. However, especially with smaller components, this does not lead to the desired reduction in crosstalk and even to a deterioration in the directionality of the radiation emission.

### SUMMARY

Embodiments provide a component, in particular an optoelectronic component, or an optoelectronic device with particularly high light extraction efficiency and improved directionality of the radiation emission with simultaneous suppression of optical crosstalk.

According to at least one embodiment of a component, it comprises a semiconductor body. The semiconductor body has a first semiconductor layer, a second semiconductor layer and an active zone located therebetween, wherein the active zone is configured to generate electromagnetic radiation. The first semiconductor layer and the second semiconductor layer can be n-conducting and p-conducting, respectively, or vice versa. For example, the active zone is a pn-junction zone. During operation of the component, the active zone is configured in particular to generate electromagnetic radiation, for example in the ultraviolet, infrared or visible spectral range. The semiconductor body is based, for example, on a III-V semiconductor compound material or on a II-VI semiconductor compound material. For example, the semiconductor body is based on a phosphide, for example InP semiconductor compound material, or on a nitride semiconductor compound material, for example a GaN semiconductor compound material.

If the semiconductor body is based on a nitride compound semiconductor material, for example, the layers of the semiconductor body can have or consist of InₙAlₘGa₁₋ₙ₋ₘN, where 0≤n≤1, 0≤m≤1 and n+m ≤1. This material does not necessarily have to have a mathematically exact composition according to the above formula. Rather, it can, for example, have one or more dopants as well as additional constituents. Two semiconductor layers based on the same semiconductor compound material can have at least two identical elements from the main groups, but in this sense do not necessarily have to have a mathematically exact composition, for example according to the above formula. This applies in particular to all semiconductor layers described here which are based on the same III-V semiconductor compound material or on the same II-VI semiconductor compound material.

According to at least one embodiment of the component, it has a cover region. In particular, the cover region is directly adjacent to the semiconductor body. The cover region is, for example, a current spreading region. The cover region can have a current spreading layer or a combination of a current spreading layer and a contact layer. It is also possible that the cover region comprises a combination of the current spreading layer and a dielectric layer, or a combination of a current spreading layer, a dielectric layer and a contact layer. For example, the cover region forms an n-conducting contact region of the component.

For example, the current spreading layer is a semiconductor layer based on the same semiconductor compound material as the semiconductor body. For example, the current spreading layer is directly adjacent to the first semiconductor layer of the semiconductor body. For example, the current spreading layer has a higher electric conductivity than the first semiconductor layer of the semiconductor body. The current spreading layer can be doped. It is also possible for the current spreading layer to have a higher metallic content than the first semiconductor layer.

The dielectric layer can be formed as a single layer or as a sequence of layers. In particular, the dielectric layer is configured to increase the efficiency of radiation extraction.

The contact layer can be formed to be radiation-transmissive. In particular, the contact layer is formed from a transparent conductive oxide (TCO). Transparent conductive oxides are transparent, conductive materials, usually metal oxides, such as zinc oxide, tin oxide, cadmium oxide, titanium oxide, indium oxide or indium tin oxide (ITO).

For example, the current spreading layer is arranged between the active zone and the dielectric layer or the contact layer. The contact layer can be arranged between the current spreading layer and the dielectric layer.

According to at least one embodiment of the component, the cover region has a larger lateral cross-section than the active zone. In plan view of the active zone, the cover region can protrude laterally beyond the active zone. The cover region thus has at least one edge region that does not overlap with the active zone when viewed from above. In plan view, the edge region can laterally enclose the active zone. For example, the cover region completely covers the active zone in plan view.

A lateral direction is understood to be a direction that is in particular parallel to a main extension surface of the active zone of the semiconductor body. A vertical direction is understood to be a direction that is in particular perpendicular to the main extension surface of the active zone. The vertical direction and the lateral direction are orthogonal to each other.

According to at least one embodiment of the component, the cover region has vertical depressions which are located at least partially or completely in the edge region of the cover region. The vertical depressions are configured, for example, to reduce lateral optical crosstalk. When viewed from above the cover region, the individual depressions can be strip-shaped, frame-like or circular arc-shaped. However, the geometry of the individual depressions is not limited to such shapes.

For example, the depressions are arranged next to each other in such a way that the neighboring depressions run parallel to each other or are aligned. Between the parallel or aligned depressions, there may be intermediate regions that are filled with material from the cover region, such as material from the current spreading layer or the contact layer or the dielectric layer. In particular, the material of the cover region and the material of the depressions have different refractive indices. Along a lateral direction, the depressions and the intermediate regions can form a Bragg mirror structure. In particular, the depressions and the intermediate regions form periodically repeating layers of the Bragg mirror structure with higher and lower refractive indices.

A Bragg mirror (Bragg reflector or distributed Bragg reflector) usually has alternating thin layers of different refractive indices. At a boundary between two layers of the Bragg mirror, part of the electromagnetic radiation can be reflected according to Fresnel's formulae. In particular, if the wavelength is close to four times the optical path length of the layers, the reflected radiation can interfere constructively. In a wavelength range wherein reflection is particularly favored, electromagnetic radiation cannot propagate in the Bragg mirror.

The depressions can, for example, be filled with a material, in particular a dielectric material, which has a lower or higher refractive index compared to the material of the intermediate regions. It is possible that the depressions are filled with a gaseous medium, such as air.

Not only is optical crosstalk suppressed by the presence of the Bragg mirror structure, but the orientation of the radiation emission can also be adjusted by the arrangement of the depressions. Since the depressions generally reflect electromagnetic radiation and do not absorb it, high light extraction efficiency can be achieved. In other words, a high light extraction efficiency, improved directionality of the radiation emission and suppression of optical crosstalk can be achieved simultaneously by suitable arrangement of the depressions.

In at least one embodiment of a component, it has a semiconductor body and a cover region. The semiconductor body has a first semiconductor layer, a second semiconductor layer and an active zone arranged therebetween configured to generate electromagnetic radiation. The cover region is configured to electrically contact the first semiconductor layer. The cover region has a larger lateral cross-section than the active zone and an edge region, wherein the edge region does not overlap with the active zone in plan view. The cover region has vertical depressions which are located at least partially in the edge region of the cover region, wherein the vertical depressions are configured to reduce lateral optical crosstalk.

For example, the component is a light-emitting semiconductor chip, such as an LED, in particular a μLED. It is possible for the component to form part of an optoelectronic device. Such a device can be a display. The device may have a plurality of subsections, wherein each of the subsections is formed by a component, in particular by a component described herein. Each subsection may form a subpixel. The subpixel may be configured to emit red, green or blue light. Depending on an RGB color space system or on a CMYK color space system, a pixel may have three or four subpixels and thus three or four components. It is possible for the optoelectronic device to have several components arranged in an array or matrix. The cover regions of the components can form a common cover region of the optoelectronic device. In particular, two neighboring ones can share a common Bragg mirror structure.

The Bragg mirror structure in the cover region can improve the light extraction and the directionality of the extracted light while maintaining the function of the cover region for current spreading. In addition, the depressions can help suppress or reduce optical crosstalk between the components. This is desirable because otherwise the optical crosstalk can lead to simultaneous illumination of neighboring pixels when only a single pixel is activated.

According to at least one embodiment of the component, the vertical depressions are located exclusively in the edge region of the cover region. In plan view, the vertical depressions do not overlap with the active zone. In particular, the edge region comprises all partial regions of the cover region that do not overlap with the active zone in plan view.

According to at least one embodiment of the component, the vertical depressions are spatially spaced from one another along a lateral direction. The vertical depressions can at least sectionally form a Bragg mirror structure. In particular, the vertical directions are spatially spaced from each other by lateral intermediate regions. The Bragg mirror structure can be formed by an arrangement of the alternately arranged vertical depressions and lateral intermediate regions.

According to at least one embodiment of the component, the vertical depressions form a symmetrical structure around the active zone when viewed from above. The symmetrical structure can be square, rectangular or circular. For example, the vertical depressions form a frame-like or circular structure around the active zone when viewed from above.

According to at least one embodiment of the component, the cover region has a transparent electrically conductive contact layer, with the vertical depressions extending into or throughout transparent electrically conductive contact layer. For example, the component has a radiation exit surface formed by the surface of the transparent electrically conductive contact layer.

According to at least one embodiment of the component, the cover region has a dielectric layer, wherein the vertical depressions extend into the dielectric layer or throughout dielectric layer. For example, the component has a radiation exit surface formed by the surface of the dielectric layer.

According to at least one embodiment of the component, the cover region has a current spreading layer, wherein the vertical depressions extend into the current spreading layer or throughout current spreading layer. The current spreading layer can be a semiconductor layer. For example, the current spreading layer and the first semiconductor layer are based on the same semiconductor compound material.

According to at least one embodiment of the component, the cover region has a transparent electrically conductive contact layer and a current spreading layer. The current spreading layer is arranged between the active zone and the transparent electrically conductive contact layer. For example, the vertical depressions extend throughout transparent electrically conductive contact layer. For example, the vertical depressions extend into the current spreading layer or throughout current spreading layer. It is possible that the transparent electrically conductive contact layer is directly adjacent to the current spreading layer.

According to at least one embodiment of the component, the cover region has a dielectric layer and a current spreading layer. The current spreading layer is arranged between the active zone and the dielectric layer. For example, the vertical depressions extend throughout dielectric layer. For example, the vertical depressions extend into the current spreading layer or throughout current spreading layer. It is possible for the dielectric layer to be directly adjacent to the current spreading layer.

According to at least one embodiment of the component, the transparent electrically conductive contact layer and/or the current spreading layer and/or the dielectric layer are/is each formed to be contiguous. The cover region can have at least two or three layers arranged one above the other, for example the current spreading layer and the transparent electrically conductive contact layer and/or the dielectric layer, wherein the at least two or three layers arranged one above the other can each be formed to be contiguous despite the presence of the vertical depressions.

However, it is possible for the contact layer to be contiguous and the current spreading layer to be discontinuous. In this case, the vertical depressions are located at least partially within the current spreading layer, for example. Due to the presence of the depressions, the current spreading layer can be divided into a plurality of spatially separated sublayers. Furthermore, it is possible that the contact layer is not contiguous, but the current spreading layer is contiguous. In this case, the vertical depressions are located, for example, at least partially within the contact layer, wherein the contact layer can be divided into a plurality of separate sublayers due to the presence of the depressions.

According to at least one embodiment of the component, the cover region has a transparent electrically conductive contact layer and a current spreading layer, wherein the current spreading layer is arranged between the active zone and the transparent electrically conductive contact layer. The vertical depressions can extend into the transparent electrically conductive contact layer or throughout transparent electrically conductive contact layer, wherein the vertical depressions do not extend into the current spreading layer, for example.

According to at least one embodiment of the component, the cover region has a dielectric layer and a current spreading layer, wherein the current spreading layer is arranged between the active zone and the dielectric layer. The vertical depressions may extend into the dielectric layer or throughout dielectric layer, wherein the vertical depressions do not extend into the current spreading layer, for example.

According to at least one embodiment of the component, the vertical depressions do not extend into the transparent electrically conductive contact layer or do not extend into the dielectric layer, wherein the vertical depressions extend into the current spreading layer or throughout current spreading layer.

According to at least one embodiment of the component, the vertical depressions extend throughout the current spreading layer, wherein at least some of the vertical depressions are formed to be frame-like or circular, as a result of which the current spreading layer is not formed to be contiguous. In this case, the current spreading layer may have a plurality of spatially separated sublayers. The spatially separated sublayers can, for example, be electrically conductively connected to each other via the contact layer, which is formed to be contiguous in particular. In particular, the contact layer is directly adjacent to all sublayers of the current spreading layer.

According to at least one embodiment of the component, the current spreading layer and the semiconductor body are based on the same semiconductor composite material. For example, the current spreading layer has a higher electric conductivity compared to the first semiconductor layer of the semiconductor body. For example, the current spreading layer is doped, or more highly doped, compared to the first semiconductor layer. It is also possible that the current spreading layer has a higher metallic content compared to the first semiconductor layer.

According to at least one embodiment of the component, the vertical depressions are arranged next to each other in plan view and are laterally spaced from each other by at least one intermediate region or by intermediate regions. The intermediate regions can be filled by a material of the cover region. For example, the intermediate regions are formed from material of the current spreading layer and/or the contact layer and/or the dielectric layer.

According to at least one embodiment of the component, at least some of the vertical depressions are arranged side by side, wherein the side by side arranged depressions form a Bragg mirror structure together with material of the cover region, for example with material of the current spreading layer and/or the contact layer and/or the dielectric layer.

According to at least one embodiment of the component, the vertical depressions are filled with a gaseous medium, for example air. It is also possible that the vertical depressions are partially or completely filled with a medium in a solid aggregate state. For example, the filled medium and material of the cover region have different refractive indices. The depressions together with the material of the cover region can form a Bragg mirror structure.

In at least one embodiment of an optoelectronic device, it has a plurality of components. The components are located adjacent to each other. The vertical depressions of the respective components are configured to reduce lateral optical crosstalk between the adjacent components. The optoelectronic device may have a plurality of components described herein. The features described in connection with the component can therefore also be used for the optoelectronic device, and vice versa.

According to at least one embodiment of the optoelectronic device, it has a common contiguous cover region, wherein the common contiguous cover region is formed from the cover regions of the components arranged next to each other.

Further embodiments and further implementations of the component or of the optoelectronic device are apparent from the exemplary embodiments explained below in connection with FIGS. 1 to 9B.

### BRIEF DESCRIPTION OF THE DRAWINGS

FIG. 1 shows a schematic representation of a comparative example of a component in three-dimensional view;

FIG. 2 shows schematic representation of an example of a component in three-dimensional view;

FIGS. 3A, 3B, 4A, 4B, 4C and 4D show schematic representations of further embodiments of a component, each in sectional view;

FIGS. 5, 6 and 7 show schematic representations of further embodiments of a component, each in plan view;

FIGS. 8A, 8B and 8C show schematic representations of some simulation results in connection with some embodiments of a component; and

FIGS. 9A and 9B show schematic representations of an embodiment of an optoelectronic device in sectional view and in plan view.

### DETAILED DESCRIPTION OF ILLUSTRATIVE EMBODIMENTS

Identical, equivalent or equivalently acting elements are indicated with the same reference numerals in the figures. The figures are schematic illustrations and thus not necessarily true to scale. Comparatively small elements and particularly layer thicknesses can rather be illustrated exaggeratedly large for the purpose of better clarification.

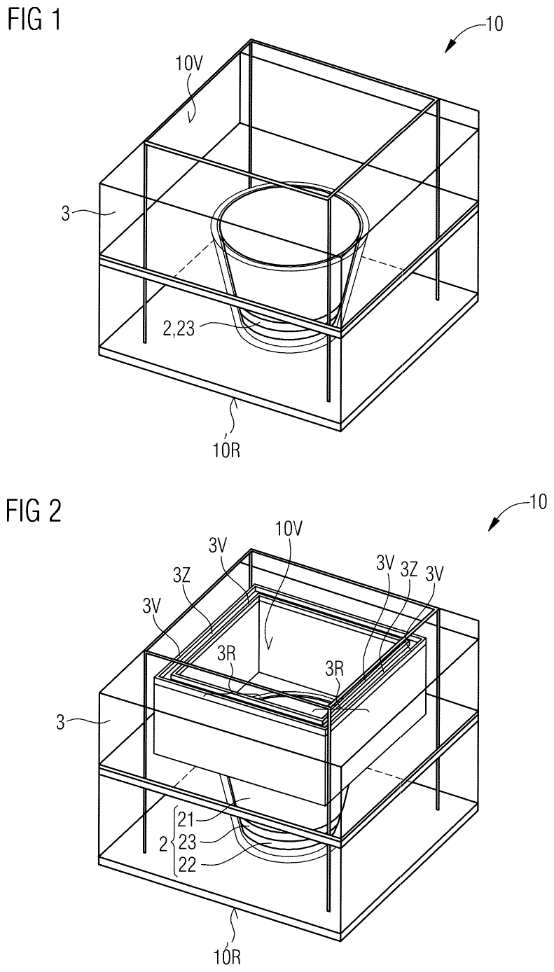

FIG. 1 shows a comparative example of a component 10 with a semiconductor body 2 and a cover region 3. The semiconductor body 2 has an active zone 23 which is configured to generate electromagnetic radiation. For example, the component 10 can be electrically externally connected via a bottom side 10R and via a top side 10V. It is possible that the top side 10V is formed by a surface of the cover region 3.

To achieve sufficient lateral current spreading, the cover region 3 typically has a vertical layer thickness between 0.5 μm and a few micrometers inclusive, for example from 0.5 μm to 5 μm or from 1 μm to 3 μm. The electromagnetic radiation generated in the active zone 23 penetrates the cover region 3 before being emitted at the top side 10V. Within the cover region 3, however, the electromagnetic radiation can spread laterally, which impairs the vertical directionality of the radiation emission. Furthermore, there is a risk of optical crosstalk if several components 10 are arranged next to each other.

The semiconductor body 2 can be surrounded in plan view by a reflector, for example in the form of a metal grid, so that lateral crosstalk is suppressed or prevented. However, the implementation of such a reflector, for example in the form of a metal grid, is technically very complex and cost-intensive. An alternative solution is therefore sought to reduce the risk of optical crosstalk. In particular, the component 10 described here is free of a reflector, for example in the form of a metal grid in the cover region 3.

In order to suppress the optical crosstalk and to achieve an improved directionality of the radiation emission, it is proposed, according to the exemplary embodiment of a component 10 shown in FIG. 2, to implement or form vertical depressions 3V in the cover region 3. For example, the vertical depressions 3V are located in an edge region 3R of the cover region 3, wherein the edge region 3R does not cover the active zone 23 in plan view of the semiconductor body 2. In other words, the edge region 3R and the active zone 23 do not overlap in plan view.

The vertical depressions 3V may be formed by an etching process or by structured application of a layer of the cover region 3.

The semiconductor body 2 has a first semiconductor layer 21 of a first charge carrier type and a second semiconductor layer 22 of a second charge carrier type, wherein the active zone 23 is arranged along the vertical direction between the first semiconductor layer 21 and the second semiconductor layer 22. It is possible that the edge region 3R and/or the vertical depressions 3V do/does not have overlaps with either the first semiconductor layer 21 or the second semiconductor layer 22 in plan view.

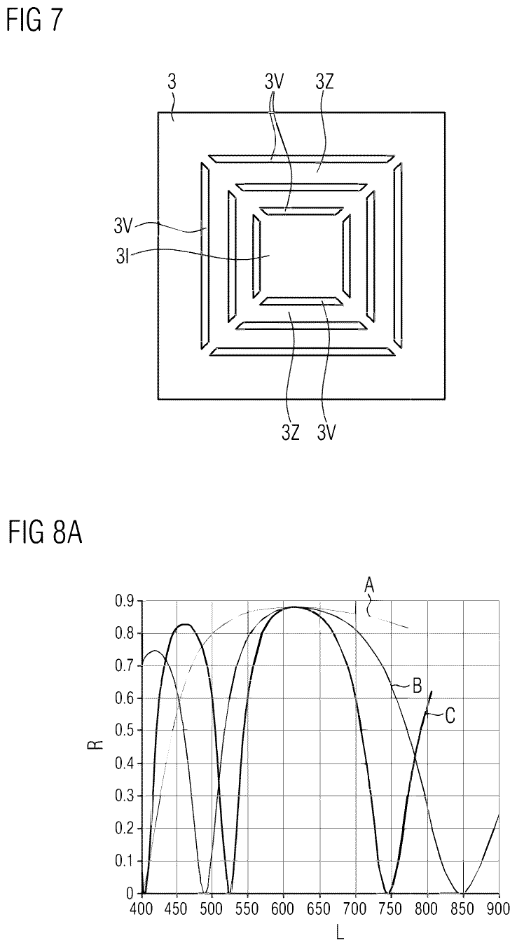

According to FIG. 2, the depressions 3V are spaced from each other by an intermediate region 3Z. FIG. 2 schematically shows two frame-like depressions 3V. It is possible that the component 10 has more than two depressions 3V. In this case, the depressions 3V can each be spaced laterally from one another by one of the intermediate regions 3Z. In FIG. 2, the depressions 3V are each contiguous and frame-like. Deviating from this, it is possible that the frame-like depressions 3V are not contiguous but interrupted. In other words, several in particular strip-shaped depressions 3V can form a frame-like structure, wherein the strip-shaped depressions 3V are not directly adjacent to one another (see for example FIGS. 5 and 7).

The cover region 3 has an inner region 3I which, in plan view, covers, in particular can completely cover, the first semiconductor layer 21, the active zone 23 and/or the second semiconductor layer 22. The depressions 3V are located in particular outside the inner region 3I of the cover region 3. For example, the inner region 3I of the cover region 3 is enclosed by the depressions 3V in lateral directions. If electromagnetic radiation is generated in the active zone 23, it first reaches the inner region 3I of the cover region 3. If the electromagnetic radiation spreads along lateral directions within the cover region 3, the electromagnetic radiation can be reflected in particular at the interfaces between the intermediate region 3Z and the depressions 3V.

In FIG. 2, the depressions 3V are formed like a frame around the inner region 31 of the cover region 3. Deviating from this, it is possible that the depressions 3V are formed in the shape of a circular arc and are arranged, for example, in such a way that the depressions 3V enclose the inner region 3I of the cover region 3 in plan view.

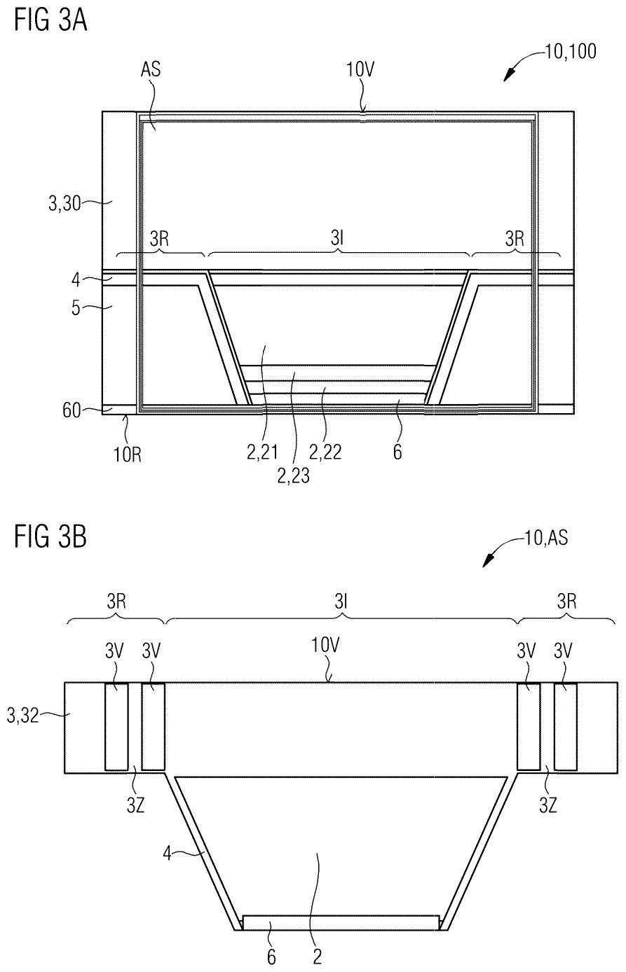

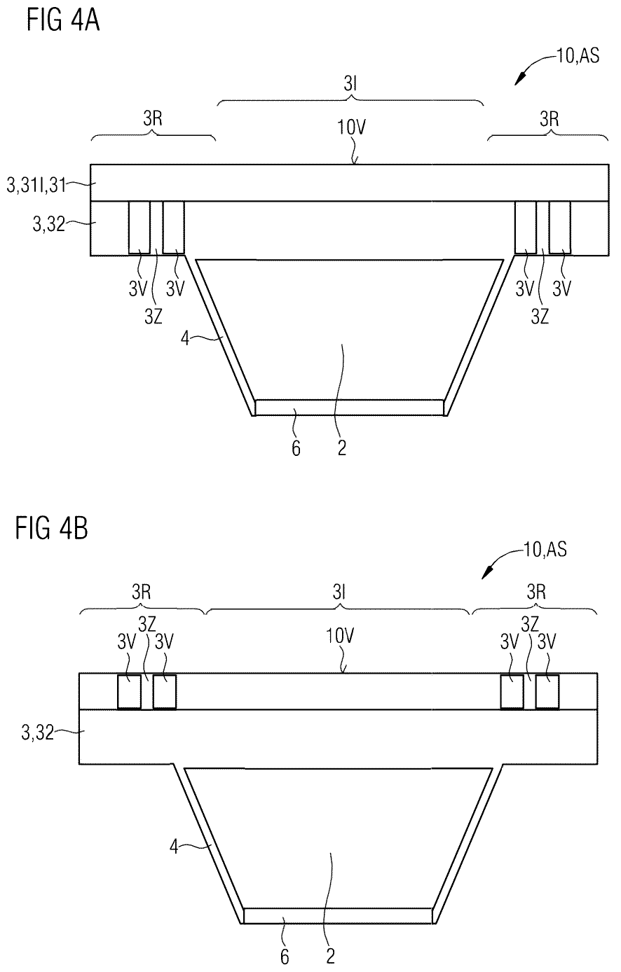

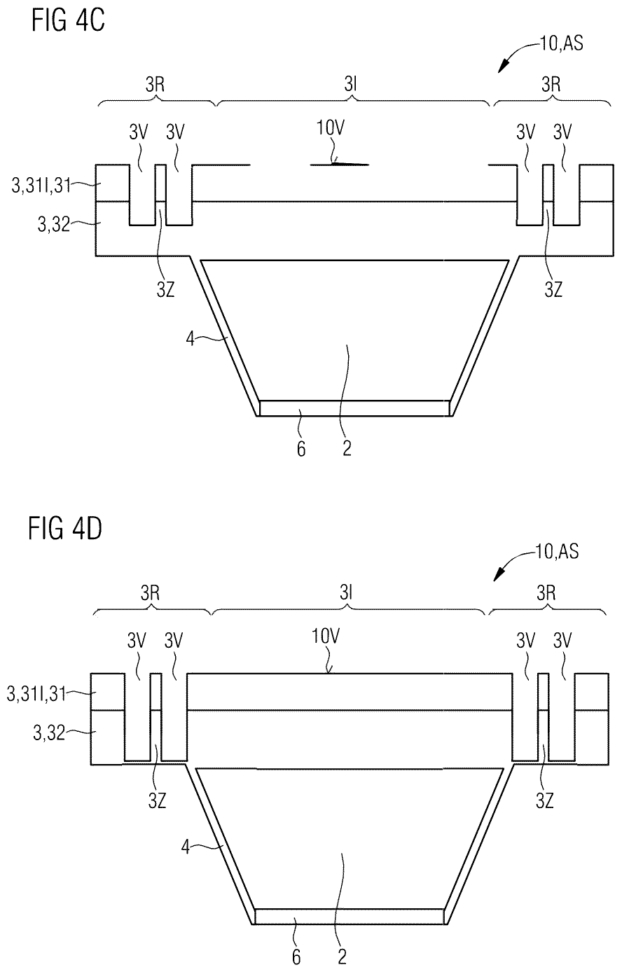

FIG. 3A shows a component 10 shown, for example, in FIGS. 1 and 2. The depressions 3V shown in FIG. 2 are not explicitly shown in FIG. 3A for reasons of clarity. In contrast, various design forms of the depressions 3V within the cover region 3 are explicitly shown in FIGS. 3B, 4A, 4B, 4C and 4D.

According to FIG. 3A, the semiconductor body 2 is surrounded in the lateral direction by an encapsulation layer 4. The encapsulation layer 4 is, for example, an insulating layer or a sequence of layers of electrically insulating materials. Furthermore, the semiconductor body 2 may be surrounded in the lateral direction by a filling layer 5, wherein the encapsulation layer 4 is arranged along the lateral direction between the semiconductor body 2 and the filling layer 5. The filling layer 5 is formed to be electrically insulating, for example. For instance, the filling layer 5 is formed from a potting material. The filling layer 5 can form a shaped body. Along the vertical direction, the encapsulation layer 4 can be arranged sectionally between the filling layer 5 and the edge region 3R of the cover region 3.

As shown schematically in FIGS. 1 to 3A, the semiconductor body 2 has a lateral cross-section that decreases with increasing distance from the cover region 3. The semiconductor body 2 thus has oblique side surfaces. This simplifies the application of the encapsulation layer 4 to the oblique side surfaces of the semiconductor body 2.

The component 10 has a further contact layer 6, such as a lower contact layer 6, which is configured for electrically contacting the second semiconductor layer 22. In particular, the further contact layer 6 is located on the bottom side 10R of the component 10. The component 10 may have a bottom end layer 60. For example, the bottom end layer 60 covers the filling layer 5 at least partially or completely. The end layer 60 can be electrically insulating or electrically conductive. If the end layer 60 is electrically insulating, it can have at least one opening at the location of the lower contact layer 6, so that the lower contact layer 6 is accessible from the outside.

An optoelectronic device 100 may have a plurality of the components 10 shown in FIG. 3A. In particular, the components 10 are arranged in an array-like or matrix-like manner. It is conceivable that the optoelectronic device 100 has a common cover region 30, wherein the common cover region 30 comprises partial regions which can form the individual cover regions 3 of the components 10.

It is also possible for the optoelectronic device 100 to have a common bottom end layer 60 for several components 10 or for all components 10 of the optoelectronic device 100. In particular, the common end layer 60 is electrically insulating and has a plurality of openings wherein the further contact layers 6 of the components 10 are arranged. The further contact layers 6 of different components 10 are thus electrically insulated from one another, so that the components 10 can be controlled individually, in particular via the further contact layers 6. For example, the optoelectronic device 100 is a display or a part of a display. Such an optoelectronic device can be used, for example, in data glasses, such as AR or VR glasses.

The exemplary embodiment of a component 10 shown in FIG. 3B essentially shows a section AS of a component 10 or an optoelectronic device 100 shown in FIG. 3A, with the cover region 3 being shown in more detail. For reasons of clarity only, the filling layer 5 and the bottom end layer 60 are not shown in FIG. 3B and in the other FIGS. 4A to 4D.

The cover region 3 has an edge region 3R with vertical depressions 3V. In plan view, the edge region 3R can partially or completely enclose the semiconductor body 2 or the active zone 23 of the semiconductor body 2 in the lateral direction. The cover region 3 has a current spreading layer 32 or, in particular, consists exclusively of a current spreading layer 32. The current spreading layer 32 can be a semiconductor layer. For example, a top side 10V of the component 10 is formed at least sectionally by a surface of the current spreading layer 32.

It is possible that the current spreading layer 32 and the semiconductor body 2 are based on the same semiconductor composite material. The current spreading layer 32 and the semiconductor body 2 may be formed in a common epitaxial process. For example, the current spreading layer 32 and the semiconductor body 2 are based on GaN or InP. For example, both the current spreading layer 32 and the first semiconductor layer 21 have a material composition in the form of InₙAlₘGa₁₋ₙ₋ₘN, but with different n and m. It is also possible that the current spreading layer 32 is highly doped, while the semiconductor layer 21 is low doped or undoped.

According to FIG. 3B, the vertical depressions 3V extend in particular throughout the current spreading layer 32. Deviating from this, it is possible that the vertical depressions 3V only extend into the current spreading layer 32. The vertical directions 3V are spaced from each other in lateral directions by an intermediate region 3Z. In FIG. 3B, only two depressions 3V are schematically shown in a left edge region 3R and in a right edge region 3R. Deviating from this, it is possible that the edge region 3R has more than two, three, four or five depressions 3V. In this case, there are several intermediate regions 3Z between the different pairs of adjacent depressions 3V.

In particular, the depressions 3V and the intermediate regions 3Z arranged between the depressions form a Bragg mirror structure. The depressions 3V can be filled with air or with a solid medium, for example with an electrically insulating material such as silicon oxide. The intermediate regions 3Z are partial regions of the cover region 3 and are thus formed from a material of the cover region 3. In particular, a refractive index of the intermediate region 3Z differs from a refractive index of the material of the adjacent depression 3V by at most 0.1, 0.2, 0.3, or at most 0.5, for example by a value between 0.05 and 0.5 inclusive, or between 0.1 and 0.2 inclusive.

The exemplary embodiment of a component 10 shown in FIG. 4A essentially corresponds to the exemplary embodiment shown in FIG. 3B. In contrast to this, the cover region 3 has a contact layer 31 and/or a dielectric layer 31I. For example, the contact layer 31 or the dielectric layer 31I is directly adjacent to the current spreading layer 32. In particular, the layer 31 is formed from a transparent electrically conductive material. The dielectric layer 31I is formed from a dielectric material or dielectric materials. The top side 10V of the component 10 may be formed by a surface of the contact layer 31 or the dielectric layer 31I. In plan view, the contact layer 31 or the dielectric layer 31I may completely cover the current spreading layer 32.

According to FIG. 4A, it is possible that the vertical depressions 3V divide the current spreading layer 32 into several spatially spaced sublayers. Due to the presence of the contact layer 31, which can in particular be directly adjacent to all the spatially spaced sublayers of the current spreading layer 32, the sublayers of the current spreading layer 32 can still be electrically connected to one another via the contact layer 31.

According to FIG. 4A, the vertical depressions 3V are only formed in the current spreading layer 32. The contact layer 31 and/or the dielectric layer 31I may be free of vertical depressions 3V.

The exemplary embodiment of a component 10 shown in FIG. 4B essentially corresponds to the exemplary embodiment of a component 10 shown in FIG. 4A. In contrast to this, the vertical depressions 3V are only formed in the contact layer 31 and/or in the dielectric layer 31I. Along the vertical direction, the depressions 3V can extend into the contact layer 31 and/or into the dielectric layer 31I or throughout contact layer 31 and/or throughout dielectric layer 31I. In particular, the current spreading layer 32 is free of the vertical depressions 3V. According to FIG. 4B, the intermediate regions 3Z are formed from a material of the contact layer 31 and/or from a material of the dielectric layer 31I.

The exemplary embodiment of a component 10 shown in FIG. 4C essentially corresponds to the exemplary embodiment of a component 10 shown in FIG. 4B. In contrast to this, the depressions 3V extend along the vertical direction throughout contact layer 31 and/or throughout dielectric layer 31I into the current spreading layer 32. According to FIG. 4C, the intermediate regions 3Z are formed sectionally from a material of the current spreading layer 32 and sectionally from a material of the contact layer 31 or the dielectric layer 31I.

The exemplary embodiment of a component 10 shown in FIG. 4D essentially corresponds to the exemplary embodiment of a component 10 shown in FIG. 4C. In contrast to this, the depressions 3V extend along the vertical direction both throughout contact layer 31 and/or the dielectric layer 31I and throughout current spreading layer 32.

FIG. 5 shows a possible arrangement of the vertical depressions 3V in the cover region 3. In particular, the depressions 3V are arranged in such a way that, in plan view, an inner region 31 of the cover region 3 is laterally enclosed by the depressions 3V. For example, in plan view, depressions 3V form a symmetrical structure. In plan view, the inner region 3I may partially or completely cover the active zone 23 of the semiconductor body 2. In plan view, the depressions 3V may form a plurality of interrupted frame-like structures enclosing the inner region 3I.

FIG. 5 shows two interrupted frame-like structures around the inner region 3I and a contiguous intermediate region 3Z located between the frame-like structures. Deviating from FIG. 5, it is possible that the depressions 3V are arranged in such a way that the depressions 3V form more than two, three, four or more than five frame-like structures around the inner region 3I. In this case the cover region 3 can have several intermediate regions 3Z. For example, the number of intermediate regions 3Z is between 1 and 10 inclusive, between 2 and 10 inclusive, between 2 and 8 inclusive or between 3 and 6 inclusive.

For example, the depressions 3V and the intermediate regions 3Z sectionally form a Bragg mirror structure or several Bragg mirror structures. In particular, the following condition applies to the optical path length of the layers of such a Bragg mirror structure:

$$n 1 * d 1 = n 2 * d 2 = ( 2 k - 1 ) * L / 4 ,$$

where k is a natural number, n1 and n2 are refractive indices of the adjacent layers with layer thicknesses d1 and d2 respectively, and L is the peak wavelength of the electromagnetic radiation.

According to the above formula, the lateral widths of the depressions 3V, the lateral widths of the intermediate regions 3Z and the filling materials of the intermediate regions 3Z and the depressions 3V can be selected to achieve an optimized Bragg mirror structure in the cover region 3, in particular in the edge region 3R of the cover region 3. Such an optimized Bragg mirror structure can reflect electromagnetic radiation in a broad spectrum of light and in a wide range of angles of incidence.

As shown schematically in FIG. 5, the depressions 3V each have a lateral width d1. The intermediate regions 3Z each have a lateral width d2. Depending on the refractive indices n1 and n2 of the materials located in the intermediate regions 3Z and in the depressions 3V, the widths d1 and d2 can be selected such that electromagnetic radiation, in particular with a peak wavelength L, is effectively reflected at the interfaces between the depressions 3V and the intermediate regions 3Z.

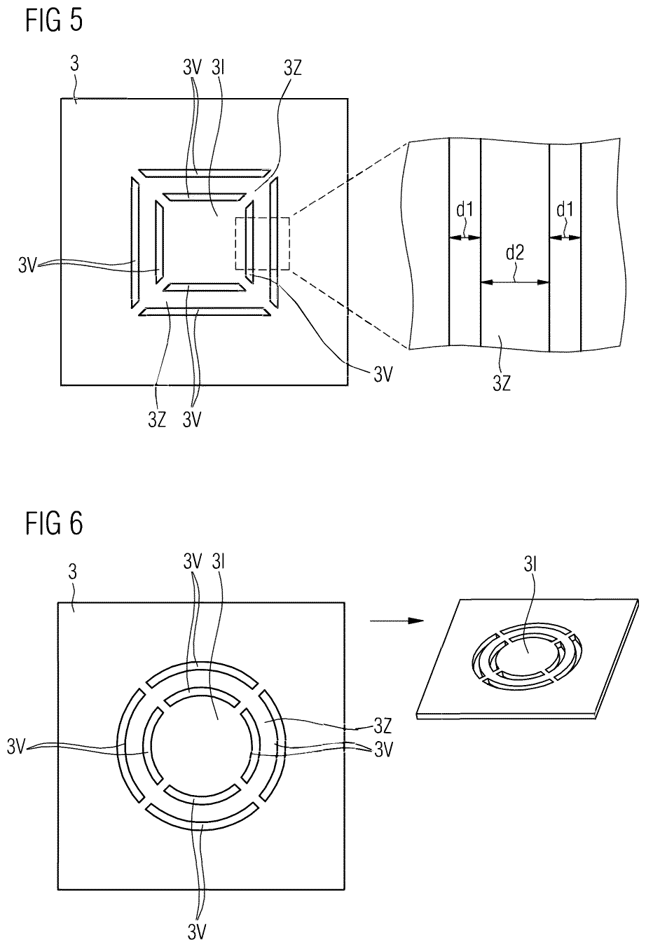

The exemplary embodiment of a component 10 shown in FIG. 6 essentially corresponds to the exemplary embodiment of a component 10 shown in FIG. 5. In contrast to this, the depressions 3V are circular in plan view. The inner region 3I is enclosed in the lateral direction by interrupted circular structures.

The exemplary embodiment of a component 10 shown in FIG. 7 essentially corresponds to the exemplary embodiment of a component 10 shown in FIG. 5. In contrast to this, the inner region 3I is enclosed in lateral directions by three interrupted frame-like structures consisting of the depressions 3V and by two contiguous intermediate regions 3Z.

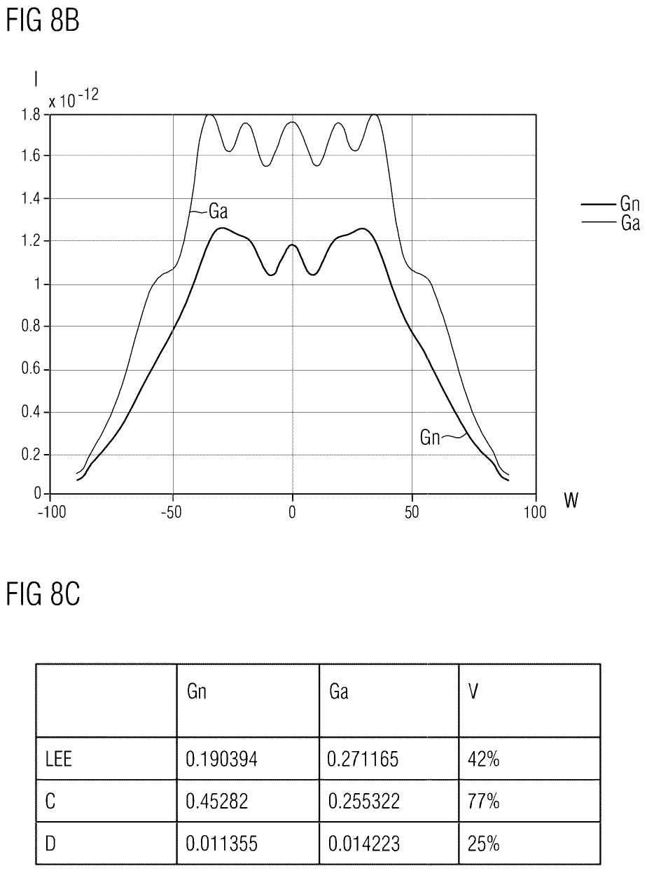

FIG. 8A shows results of a simulation based on the exemplary embodiment shown in FIG. 5, wherein the depressions 3V are filled with air and the intermediate region 3Z is based on GaN. In this simulation, the following values are used for the widths d1 and d2: d1=153 nm; d2=65 nm (curve A); d2=198 nm (curve B) and d2=327 nm (curve C). The reflectivity R is shown as a function of the wavelength L. It has been shown that high reflectivity R of up to 90% can be achieved with two adjacent depressions 3V and a single intermediate region 3Z.

FIG. 8B shows the results of further simulations. Curve Ga shows the radiation intensity I as a function of the angular distribution W in the far field for the case that the cover region 3 has depressions 3V that are filled with air. Curve Gn shows the radiation intensity I as a function of the angular distribution W in the far field for the case that the cover region 3 has no depressions 3V. In the presence of the depressions 3V, a clear improvement in the orientation of the radiation emission can be observed.

FIG. 8C shows simulation results of GaN μLED for the case Ga that the cover region 3 has depression 3V filled with air and for the case Gn that the cover region 3 has no depression 3V. Significant improvements V can be achieved both in the light extraction efficiency LEE and in the suppression of optical crosstalk C as well as in the directionality D of the radiant emission. C is defined here as the part of the radiation that does not emerge vertically from the component 10 and is directed to the side. D or directionality is defined here as LEE within a half angle of 9°, which is based on both the total LEE and the far field emission.

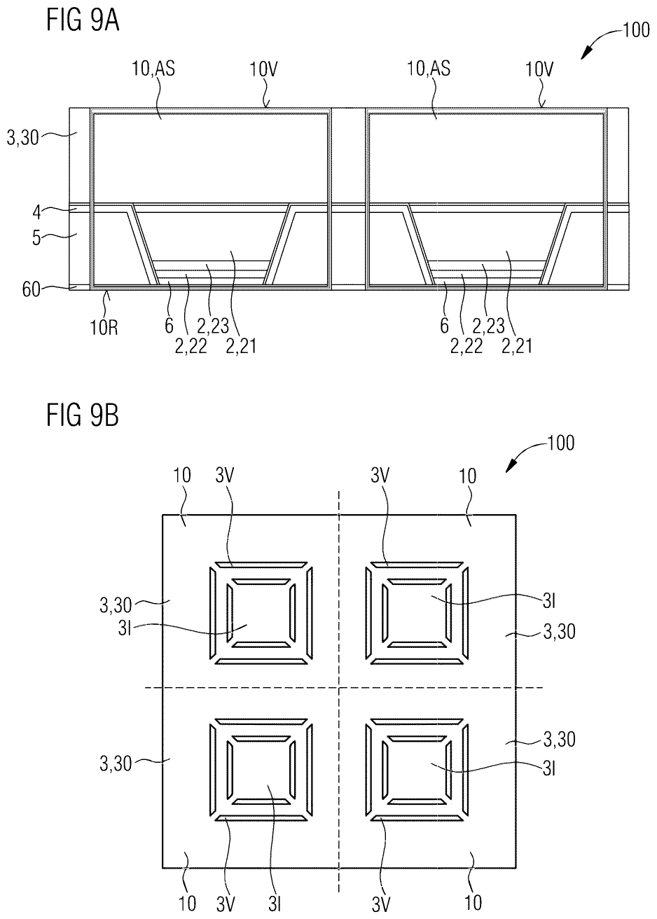

FIG. 9A shows an exemplary embodiment of an optoelectronic device 100 with a plurality of components 10. It is possible that the components 10 share a common cover layer 30 and/or a common end layer 60 of the optoelectronic device 100. The components 10 can be arranged next to each other in rows or in a matrix. FIG. 9B shows as an example an optoelectronic device 100 with four of such components 10 in plan view. Deviating from FIG. 9B, the optoelectronic device 100 can have more than 4, 10, 100 or more than 1000 such components 10.

With the application of vertical depressions 3V in the cover region 3, a high performance component 10 with high LEE and improved radiation emission directionality can be easily fabricated. In contrast to, for example, the formation of photonic crystal patterns in the cover region 3, high tolerance and high flexibility in the formation of the vertical depressions 3V can be achieved. The presence of the depressions 3V leads to the improvement of the light extraction efficiency and the directionality of the radiation emission while reducing the crosstalk. Depending on the degree of crosstalk suppression required, a flexible number of vertical depressions 3V can be used to form several Bragg mirror structures.

This application claims the priority of the German patent application 10 2021 129 118.6, the disclosure content of which is hereby included by reference.

The invention is not restricted to the exemplary embodiments by the description of the invention made with reference to the exemplary embodiments. The invention rather comprises any novel feature and any combination of features, including in particular any combination of features in the claims, even if this feature or this combination is not itself explicitly indicated in the patent claims or exemplary embodiments.

1.-18. (canceled)

19. A component comprising:
a semiconductor body; and
a cover region,
wherein the semiconductor body has a first semiconductor layer, a second semiconductor layer and an active zone arranged therebetween, the active zone configured for generating electromagnetic radiation,
wherein the cover region is configured for electrically contacting the first semiconductor layer, and
wherein the cover region comprises:
a larger lateral cross-section than the active zone and has an edge region, which does not overlap with the active zone in plan view, and
vertical depressions, which are located exclusively in the edge region of the cover region and, in plan view, do not overlap with the active zone, the vertical depressions being configured to reduce lateral optical crosstalk.

20. The component according to claim 19, wherein each of the vertical depressions is strip-shaped or circular-arc-shaped when viewed from above on the cover region.

21. The component according to claim 19, wherein the vertical depressions are spaced apart along a lateral direction and at least sectionally form a Bragg mirror structure.

22. The component according to claim 19, wherein the vertical depressions form a symmetrical structure around the active zone when viewed from above.

23. The component according to claim 19, wherein the cover region comprises a transparent electrically conductive contact layer and/or a dielectric layer, and wherein the vertical depressions extend into the transparent electrically conductive contact layer and/or the dielectric layer or throughout the transparent electrically conductive contact layer and/or the dielectric layer.

24. The component according to claim 19, wherein the cover region comprises a current spreading layer, and wherein the vertical depressions extend into the current spreading layer or throughout the current spreading layer.

25. The component according to claim 24, wherein the current spreading layer and the semiconductor body are based on the same semiconductor composite material, and wherein the current spreading layer has a higher electric conductivity compared to the first semiconductor layer of the semiconductor body.

26. The component according to claim 19,
wherein the cover region has a current spreading layer and additionally a transparent electrically conductive contact layer and/or a dielectric layer,
wherein the current spreading layer is arranged between the active zone and the transparent electrically conductive contact layer or the dielectric layer,
wherein the vertical depressions extend throughout transparent electrically conductive contact layer and/or the dielectric layer, and
wherein the vertical depressions extend into the current spreading layer or throughout current spreading layer.

27. The component according to claim 26, wherein the transparent electrically conductive contact layer and/or the current spreading layer and/or the dielectric layer are/is each contiguous.

28. The component according to claim 19,
wherein the cover region has a current spreading layer and additionally a transparent electrically conductive contact layer and/or a dielectric layer,
wherein the current spreading layer is arranged between the active zone and the transparent electrically conductive contact layer or the dielectric layer,
wherein the vertical depressions extend into the transparent electrically conductive contact layer and/or the dielectric layer or throughout transparent electrically conductive contact layer and/or the dielectric layer, and
wherein the vertical depressions do not extend into the current spreading layer.

29. The component according to claim 19,
wherein the cover region has a current spreading layer and additionally a transparent electrically conductive contact layer and/or a dielectric layer,
wherein the current spreading layer is arranged between the active zone and the transparent electrically conductive contact layer or the dielectric layer,
wherein the vertical depressions do not extend into the transparent electrically conductive contact layer and/or the dielectric layer, and
wherein the vertical depressions extend into the current spreading layer or throughout current spreading layer.

30. The component according to claim 29, wherein the vertical depressions extend through into the current spreading layer, at least some of the vertical depressions being of frame-like or circular shape, as a result of which the current spreading layer is non-contiguous.

31. The component according to claim 19, wherein the vertical depressions are arranged side by side in plan view and are laterally spaced from each other by intermediate regions, and wherein the intermediate regions are filled by a material of the cover region.

32. The component according to claim 19, wherein at least some of the vertical depressions are arranged side by side, the side by side arranged depressions together with material of the cover region forming a Bragg mirror structure.

33. The component according to claim 19, wherein the vertical depressions are filled with a gaseous medium.

34. The component according to claim 19, wherein the vertical depressions are filled with a medium in a solid aggregate state, wherein the filled medium and material of the cover region have different refractive indices, and wherein the depressions together with material of the cover region form a Bragg mirror structure.

35. An optoelectronic device comprising:
a plurality of components according to claim 19,
wherein the components are located next to each other and the vertical depressions of the respective components are configured to reduce the lateral optical crosstalk between adjacent components.

36. The optoelectronic device according to claim 35, wherein the optoelectronic device has a common contiguous cover region, and wherein the common contiguous cover region is formed from the cover regions of the components arranged next to one another.

37. A component comprising:
a semiconductor body; and
a cover region,
wherein the semiconductor body has a first semiconductor layer, a second semiconductor layer and an active zone arranged therebetween, the active zone configured for generating electromagnetic radiation,
wherein the cover region is configured for electrically contacting the first semiconductor layer,
wherein the cover region comprises:
a larger lateral cross-section than the active zone and has an edge region which does not overlap with the active zone in plan view, and
vertical depressions which are located exclusively in the edge region of the cover region and, in plan view, do not overlap with the active zone, the vertical depressions being configured to reduce lateral optical crosstalk, and
wherein the component is configured so that the electromagnetic radiation penetrates the cover region before being emitted at a top side of the component.

38. The component according to claim 37,
wherein the vertical depressions are arranged side by side in plan view and are laterally spaced from each other by intermediate regions, and
wherein the vertical depressions and intermediate regions form periodically repeating layers of a Bragg mirror structure with higher and lower refractive indices.
